(19) United States
(12) Patent Application Publication
(10) Pub. No.: US 2025/0183098 A1
(43) Pub. Date: Jun. 5, 2025

(54) SEMICONDUCTOR DEVICE INCLUDING CONDUCTIVE BONDING PATTERN

(71) Applicant: SK hynix Inc., Gyeonggi-do (KR)

(72) Inventor: Byung Wook BAE, Gyeonggi-do (KR)

(21) Appl. No.: 18/623,049

(22) Filed: Apr. 1, 2024

(30) Foreign Application Priority Data
Dec. 5, 2023 (KR) 10-2023-0174254

(51) Int. Cl. H01L 21/768; H01L 23/00; H01L 23/528; H01L 23/532; H01L 29/66; H10B 43/27; H10B 43/30

(52) U.S. Cl. CPC H01L 21/76897; H01L 21/76832; H01L 23/5286; H01L 23/53295; H01L 24/08; H10B 43/27; H10B 43/30; H10D 64/021; H01L 2224/08145; H01L 2924/14511

(57) ABSTRACT

A semiconductor device may include an interconnection on a substrate. An interlayer insulating layer may be disposed on the interconnection. A capping layer may be disposed on the interlayer insulating layer. A conductive bonding pattern disposed in a pad trench which passes through the capping layer and extends into the interlayer insulating layer may be provided. A spacer disposed in the pad trench and contacting a side surface of the conductive bonding pattern may be provided. A contact plug disposed in a contact hole which passes through the interlayer insulating layer and is aligned with a center of the pad trench may be provided. The contact plug may contact the interconnection. The conductive bonding pattern may be continuous to the contact plug.

### CROSS-REFERENCE TO RELATED APPLICATION

The present application claims priority under 35 U.S.C. § 119(a) to Korean Patent Application No. 10-2023-0174254 filed on Dec. 5, 2023, which is incorporated herein by reference in its entirety.

### BACKGROUND

### 1. Technical Field

Various embodiments of the present disclosure generally relate to a semiconductor device including a conductive bonding pattern and a method for forming the same.

### 2. Related Art

In response to the demand for high integration of a semiconductor device, a technology for bonding two wafers is being used. A lower wafer and an upper wafer may be bonded using insulating layers, and may be electrically connected through bonding pads disposed in the insulating layers. Each of the bonding pads may be connected to an internal integrated circuit of the lower wafer or the upper wafer through a contact plug. When the number of processes for forming the bonding pads and contact plugs increases, mass production efficiency may decrease.

### SUMMARY

Various embodiments of the present disclosure are directed to a semiconductor device capable of simplifying a process and increasing mass production efficiency, and a method for forming the same.

In an embodiment of the present disclosure, a semiconductor device may include an interconnection disposed on a substrate. An interlayer insulating layer may be disposed on the interconnection. A capping layer may be disposed on the interlayer insulating layer. A conductive bonding pattern disposed in a pad trench which passes through the capping layer and extends into the interlayer insulating layer may be provided. A spacer disposed in the pad trench and contacting a side surface of the conductive bonding pattern may be provided. A contact plug disposed in a contact hole which passes through the interlayer insulating layer and is aligned with a center of the pad trench may be provided. The contact plug may contact the interconnection. The conductive bonding pattern may be continuous to the contact plug.

In an embodiment of the present disclosure, a semiconductor device may include a first structure; and a second structure bonded onto the first structure. The first structure may include: a first integrated circuit; a first interconnection disposed on the first integrated circuit; a first interlayer insulating layer disposed on the first interconnection; a first capping layer disposed on the first interlayer insulating layer; a first conductive bonding pattern disposed in a first pad trench which passes through the first capping layer and extends into the first interlayer insulating layer; a first spacer disposed in the first pad trench, and contacting a side surface of the first conductive bonding pattern; and a first contact plug disposed in a first contact hole which passes through the first interlayer insulating layer and is aligned with a center of the first pad trench. The first contact plug may contact the first interconnection. The first conductive bonding pattern may be continuous to the first contact plug.

In an embodiment of the present disclosure, a semiconductor device may include a first structure; and a second structure bonded onto the first structure. The first structure may include a first integrated circuit; a first interconnection disposed on the first integrated circuit; a first interlayer insulating layer disposed on the first interconnection; a first capping layer disposed on the first interlayer insulating layer; a first conductive bonding pattern disposed in a first pad trench which passes through the first capping layer and extends into the first interlayer insulating layer; a first dummy pattern disposed in a first dummy trench which passes through the first capping layer and extends into the first interlayer insulating layer; a first spacer disposed in the first pad trench, and contacting a side surface of the first conductive bonding pattern; a first dummy spacer disposed in the first dummy trench, and contacting a side surface and bottom of the first dummy pattern; and a first contact plug disposed in a first contact hole which passes through the first interlayer insulating layer and is aligned with a center of the first pad trench. The first contact plug may contact the first interconnection. The first conductive bonding pattern may be continuous to the first contact plug.

According to the embodiments of the present disclosure, it is possible to implement a semiconductor device which is advantageous for simplifying a process and increasing mass production efficiency.

### BRIEF DESCRIPTION OF THE DRAWINGS

FIG. 1 is a cross-sectional view for describing a semiconductor device in accordance with an embodiment of the present disclosure.

FIGS. 2 and 3 are plan views for describing the semiconductor device in accordance with embodiments of the present disclosure.

FIG. 4 is a cross-sectional view for describing a semiconductor device in accordance with an embodiment of the present disclosure.

FIGS. 5 to 18 are cross-sectional views for describing methods for forming a semiconductor device in accordance with embodiments of the present disclosure.

### DETAILED DESCRIPTION

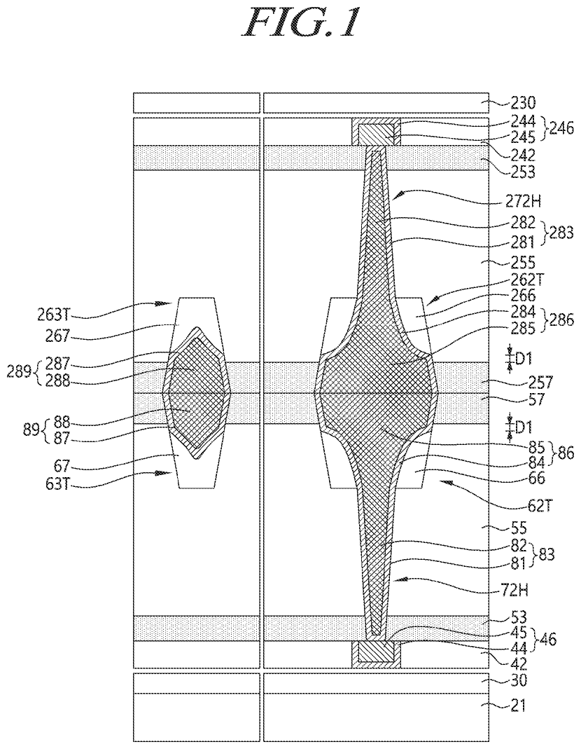

FIG. 1 is a cross-sectional view for describing a semiconductor device in accordance with an embodiment of the present disclosure.

Referring to FIG. 1, the semiconductor device may include a substrate 21, a first integrated circuit 30, a first insulating layer 42, a first interconnection 46, a first etch stop layer 53, a first interlayer insulating layer 55, a first capping layer 57, a first pad trench 62T, a first dummy trench 63T, a first spacer 66, a first dummy spacer 67, a first contact hole 72H, a first contact plug 83, a first conductive bonding pattern 86, a first dummy pattern 89, a second integrated circuit 230, a second insulating layer 242, a second interconnection 246, a second etch stop layer 253, a second interlayer insulating layer 255, a second capping layer 257, a second pad trench 262T, a second dummy trench 263T, a second spacer 266, a second dummy spacer 267, a second contact hole 272H, a second contact plug 283, a second conductive bonding pattern 286, and a second dummy pattern 289.

The first interconnection 46 may include a first barrier layer 44 and a first conductive layer 45. The first contact plug 83 may include a second barrier layer 81 and a second conductive layer 82. The first conductive bonding pattern 86 may include a third barrier layer 84 and a third conductive layer 85. The first dummy pattern 89 may include a fourth barrier layer 87 and a fourth conductive layer 88.

The second interconnection 246 may include a fifth barrier layer 244 and a fifth conductive layer 245. The second contact plug 283 may include a sixth barrier layer 281 and a sixth conductive layer 282. The second conductive bonding pattern 286 may include a seventh barrier layer 284 and a seventh conductive layer 285. The second dummy pattern 289 may include an eighth barrier layer 287 and an eighth conductive layer 288.

The first integrated circuit 30 may be disposed on the substrate 21. For example, the first integrated circuit 30 may include a memory cell array, an image sensor, a logic circuit, or a combination thereof. The first integrated circuit 30 may include various types of active/passive elements. The first integrated circuit 30 may include conductive patterns and insulating layers. The first insulating layer 42 may be disposed on the first integrated circuit 30. The first interconnection 46 may be disposed in the first insulating layer 42. The first interconnection 46 may be electrically connected to the first integrated circuit 30.

The first etch stop layer 53 may be disposed on the first insulating layer 42 and the first interconnection 46. The first interlayer insulating layer 55 may be disposed on the first etch stop layer 53. The first capping layer 57 may be disposed on the first interlayer insulating layer 55. Each of the first pad trench 62T and the first dummy trench 63T may pass through the first capping layer 57 and extend into the first interlayer insulating layer 55. The first dummy trench 63T may have a narrower width than the first pad trench 62T.

The first spacer 66 may be disposed in the first pad trench 62T, and the first dummy spacer 67 may be disposed in the first dummy trench 63T. The first spacer 66 may partially cover the sidewall and bottom of the first pad trench 62T. The first dummy spacer 67 may partially cover the sidewall of the first dummy trench 63T and completely cover the bottom of the first dummy trench 63T. The first spacer 66 and the first dummy spacer 67 may include the same material, such as silicon oxide, silicon nitride, silicon oxynitride, silicon carbonitride (SiCN), polysilicon, metal, metal oxide, metal nitride, metal silicate, or a combination thereof.

The first contact hole 72H may penetrate the bottom of the first pad trench 62T, and may pass through the first interlayer insulating layer 55 and the first etch stop layer 53. The first contact hole 72H may be aligned with the center of the first pad trench 62T. The first contact hole 72H may be self-aligned with the first spacer 66. The first spacer 66 may be disposed along the sidewall of the first pad trench 62T. The first contact hole 72H may be self-aligned inside the first spacer 66. That is, the first contact hole 72H may be aligned according to a profile the first spacer 66.

The first contact plug 83 may be disposed in the first contact hole 72H and contact the first interconnection 46. The first conductive bonding pattern 86 may be disposed in the first pad trench 62T and be continuous to the first contact plug 83. The first spacer 66 may surround the side surface of the first conductive bonding pattern 86. The first spacer 66 may contact the side surface of the first conductive bonding pattern 86. The first contact plug 83 may be aligned with the center of the first pad trench 62T. The first contact plug 83 may be self-aligned inside the first spacer 66. The first contact plug 83 may have a narrower width than the first conductive bonding pattern 86. The first contact plug 83 may be aligned with the center of the first conductive bonding pattern 86.

The first dummy pattern 89 may be disposed in the first dummy trench 63T. The first dummy spacer 67 may contact the side surface and bottom of the first dummy pattern 89. The first dummy pattern 89 may have a narrower width than the first conductive bonding pattern 86.

In an embodiment, the first spacer 66 and the first dummy spacer 67 may include silicon oxide. The uppermost ends of the first spacer 66 and the first dummy spacer 67 may be disposed at a level lower than the uppermost ends of the first conductive bonding pattern 86 and the first dummy pattern 89. The uppermost ends of the first spacer 66 and the first dummy spacer 67 may be disposed at a level lower than the lower surface of the first capping layer 57. The upper surfaces of the first capping layer 57, the first conductive bonding pattern 86 and the first dummy pattern 89 may form substantially the same plane.

The vertical distance between the lower surface of the first capping layer 57 and the uppermost end of the first spacer 66 may be a first distance D1. The vertical distance between the lower surface of the first capping layer 57 and the uppermost end of the first dummy spacer 67 may be substantially the same as the first distance D1. The first distance D1 may be 1 nm to 50 nm. In an embodiment, the first distance D1 may be about 10 nm or more. Between the lower surface of the first capping layer 57 and the uppermost end of the first spacer 66, the first interlayer insulating layer 55 may contact the side surface of the first conductive bonding pattern 86. Between the lower surface of the first capping layer 57 and the uppermost end of the first dummy spacer 67, the first interlayer insulating layer 55 may contact the side surface of the first dummy pattern 89.

In an embodiment, the substrate 21, the first integrated circuit 30, the first insulating layer 42, the first interconnection 46, the first etch stop layer 53, the first interlayer insulating layer 55, the first capping layer 57, the first pad trench 62T, the first dummy trench 63T, the first spacer 66, the first dummy spacer 67, the first contact hole 72H, the first contact plug 83, the first conductive bonding pattern 86 and the first dummy pattern 89 may configure a first structure. The second integrated circuit 230, the second insulating layer 242, the second interconnection 246, the second etch stop layer 253, the second interlayer insulating layer 255, the second capping layer 257, the second pad trench 262T, the second dummy trench 263T, the second spacer 266, the second dummy spacer 267, the second contact hole 272H, the second contact plug 283, the second conductive bonding pattern 286 and the second dummy pattern 289 may configure a second structure. Since the components included in the second structure have a similar configuration to the first structure, repeated descriptions will be omitted.

The second structure may be bonded onto the first structure. The second capping layer 257 may be bonded to the first capping layer 57 to face each other. One interface layer or a plurality of interface layers such as a plasma-oxidized layer or plasma-oxidized layers may be additionally formed between the second capping layer 257 and the first capping layer 57, descriptions thereof will be omitted for the sake of simplicity. The second conductive bonding pattern 286 may be bonded onto the first conductive bonding pattern 86, and the second dummy pattern 289 may be bonded onto the first dummy pattern 89.

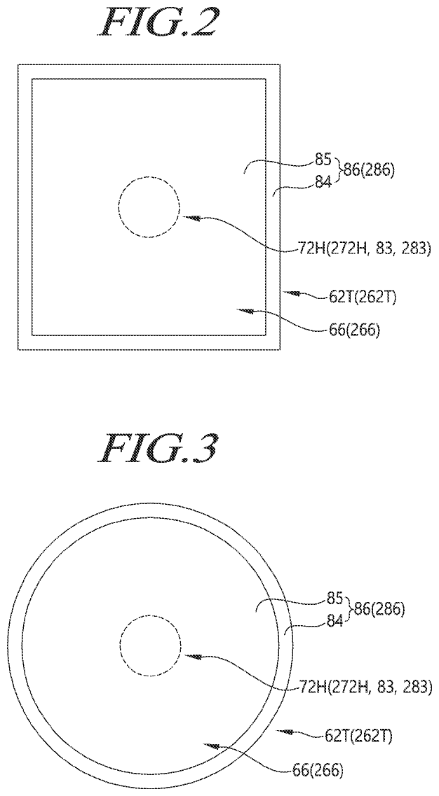

FIGS. 2 and 3 are plan views for describing the semiconductor device in accordance with embodiments of the present disclosure.

Referring to FIGS. 1 to 3, the first pad trench 62T and the first conductive bonding pattern 86 may have various shapes, such as a square, a circle or a combination thereof, when viewed in a plan view. The first spacer 66 may be disposed along the sidewall of the first pad trench 62T. The first contact hole 72H and the first contact plug 83 may be self-aligned inside the first spacer 66. The first contact hole 72H and the first contact plug 83 may be self-aligned with the center of the first conductive bonding pattern 86.

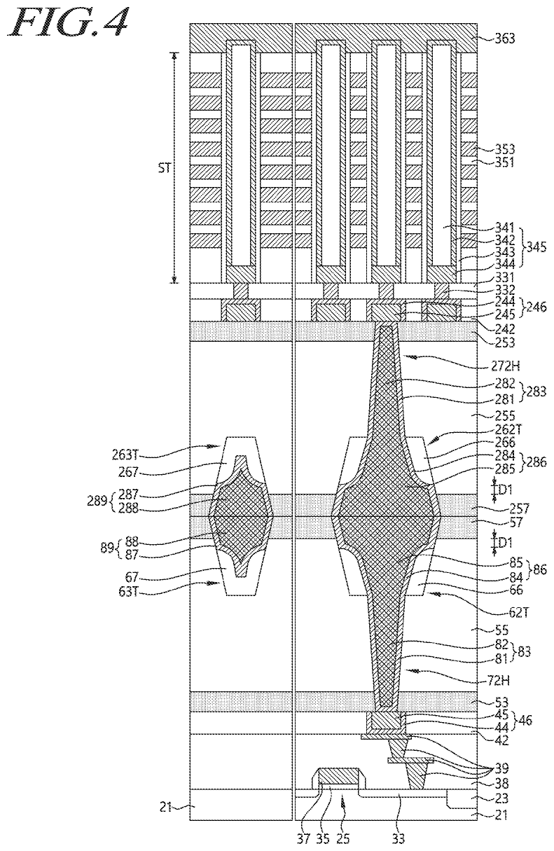

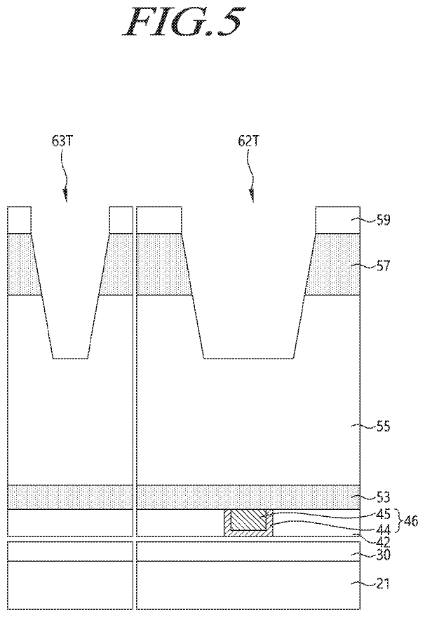

FIG. 4 is a cross-sectional view for describing a semiconductor device in accordance with an embodiment of the present disclosure.

Referring to FIG. 4, the semiconductor device may include the substrate 21, an isolation layer 23, the active region 25, source/drain regions 33, a gate dielectric layer 35, a gate electrode 37, a lower insulating layer 38, a lower interconnection 39, the first insulating layer 42, the first interconnection 46, the first etch stop layer 53, the first interlayer insulating layer 55, the first capping layer 57, the first pad trench 62T, the first dummy trench 63T, the first spacer 66, the first dummy spacer 67, the first contact hole 72H, the first contact plug 83, the first conductive bonding pattern 86, the first dummy pattern 89, the second insulating layer 242, the second interconnection 246, the second etch stop layer 253, the second Interlayer insulating layer 255, the second capping layer 257, the second pad trench 262T, the second dummy trench 263T, the second spacer 266, the second dummy spacer 267, the second contact hole 272H, the second contact plug 283, the second conductive bonding pattern 286, the second dummy pattern 289, an upper insulating layer 331, an upper plug 332, a stack structure ST, a channel pillar 345, and a source line 363.

The stack structure ST may include a plurality of mold layers 351 and a plurality of horizontal electrodes 353 which are alternately and repeatedly stacked. The channel pillar 345 may include a core layer 341, a channel pattern 342, an information storage pattern 343 and a bit plug 344.

The isolation layer 23 which defines the active region 25 may be disposed within the substrate 21. The gate electrode 37 may be disposed over the active region 25. The gate dielectric layer 35 may be interposed between the active region 25 and the gate electrode 37. The source/drain regions 33 may be disposed in the active region 25 adjacent to both sides of the gate electrode 37. The active region 25, the source/drain regions 33, the gate dielectric layer 35 and the gate electrode 37 may configure a transistor. Although a planar transistor is illustrated in FIG. 4, the transistor may be implemented as a recess channel transistor, a vertical transistor, a fin field effect transistor (finFET), a gate all around (GAA) transistor, a multi-bridge channel transistor, or a combination thereof. In an embodiment, the transistor may be a portion of a peripheral circuit such as a page buffer.

The lower insulating layer 38 which covers the source/drain regions 33 and the gate electrode 37 may be disposed on the substrate 21. The lower interconnection 39 may be disposed in the lower insulating layer 38. The lower interconnection 39 may be connected to the source/drain regions 33. The first insulating layer 42 may be disposed on the lower insulating layer 38. The first interconnection 46 may be disposed in the first insulating layer 42. Repeated descriptions for components similar to those illustrated in FIGS. 1 to 3 will be omitted.

The second interconnection 246 may be disposed in the second insulating layer 242. The upper insulating layer 331 may be disposed on the second insulating layer 242. The upper plug 332 may be disposed in the upper insulating layer 331. The upper plug 332 may be connected to the second interconnection 246. The stack structure ST may be disposed on the upper insulating layer 331. The plurality of mold layers 351 may include an insulating material such as silicon oxide. The plurality of horizontal electrodes 353 may include a conductive material such as W, WN, Ti, TiN, Ta, TaN, Ru, or a combination thereof.

The channel pillar 345 may pass through the stack structure ST in a vertical direction. The core layer 341 may be disposed at the center of the channel pillar 345. The core layer 341 may include silicon oxide, silicon nitride, silicon oxynitride, polysilicon, or a combination thereof. The channel pattern 342 may surround the side surface of the core layer 341. The channel pattern 342 may include a semiconductor material such as polysilicon. The information storage pattern 343 may surround the side surface of the channel pattern 342. The information storage pattern 343 may be disposed between the channel pattern 342 and the stack structure ST.

The information storage pattern 343 may include a tunnel layer, a charge trap layer and a blocking layer. The charge trap layer may be disposed between the tunnel layer and the blocking layer. The tunnel layer may be disposed between the channel pattern 342 and the charge trap layer. The blocking layer may be disposed between the charge trap layer and the stack structure ST. In an embodiment, the tunnel layer may include silicon oxide, the charge trap layer may include silicon nitride, and the blocking layer may include silicon oxide.

The bit plug 344 may be disposed adjacent to one end (e.g., the lower end) of the channel pillar 345. The bit plug 344 may contact the channel pattern 342 and the upper plug 332. The bit plug 344 may include a conductive material such as polysilicon, metal, metal silicide, metal nitride, or a combination thereof.

The source line 363 may be disposed on the stack structure ST. The source line 363 may include a conductive material such as polysilicon, metal, metal silicide, metal nitride, or a combination thereof. The other end (e.g., the upper end) of the channel pillar 345 may extend into the source line 363. In an embodiment, the core layer 341 and the channel pattern 342 may extend into the source line 363. The channel pattern 342 may contact the source line 363.

The source line 363 may correspond to a common source line. The plurality of horizontal electrodes 353 may include a plurality of word lines, a plurality of select lines, and at least one GIDL (gate Induced drain leakage) control line. In an embodiment, at least one horizontal electrode adjacent to the source line 363, among the plurality of horizontal electrodes 353 may correspond to a source select line. At least one horizontal electrode adjacent to the bit plug 344, among the plurality of horizontal electrodes 353 may correspond to a drain select line. One horizontal electrode adjacent to the source line 363, among the plurality of horizontal electrodes 353 and/or one horizontal electrode adjacent to the bit plug 344, among the plurality of horizontal electrodes 353 may correspond to the GIDL control line. A plurality of memory cells may be formed at intersections of the channel pillar 345 and the plurality of word lines.

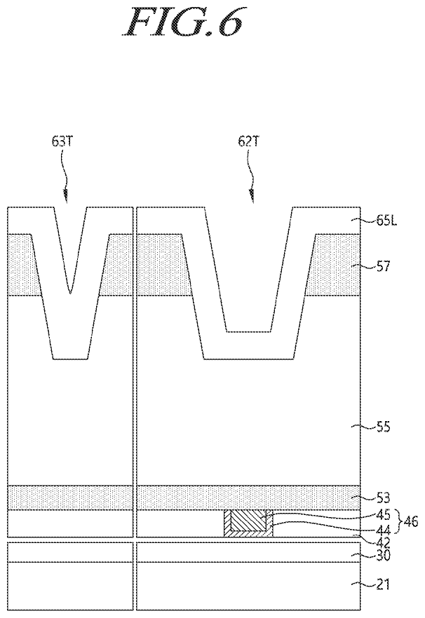

FIGS. 5 to 11 are cross-sectional views for describing a method for forming a semiconductor device in accordance with an embodiment of the present disclosure.

Referring to FIG. 5, the first integrated circuit 30 may be formed on the substrate 21. The first insulating layer 42 may be formed on the first integrated circuit 30. The first interconnection 46 which is electrically connected to the first integrated circuit 30 may be formed in the first insulating layer 42. The first interconnection 46 may include the first barrier layer 44 and the first conductive layer 45. The first etch stop layer 53 may be formed on the first insulating layer 42 and the first interconnection 46. The first interlayer insulating layer 55 may be formed on the first etch stop layer 53. The first capping layer 57 may be formed on the first interlayer insulating layer 55. A mask pattern 59 may be formed on the first capping layer 57. By etching the first capping layer 57 and the first interlayer insulating layer 55 using the mask pattern 59 as an etch mask, the first pad trench 62T and the first dummy trench 63T may be formed.

The substrate 21 may include a semiconductor substrate such as a silicon wafer or an SOI (silicon on insulator) wafer. The substrate 21 may include a III-V group semiconductor substrate, for example, a compound semiconductor substrate such as GaAs. The substrate 21 may include monocrystalline silicon, polysilicon, amorphous silicon, monocrystalline silicon germanium, polycrystalline silicon germanium, carbon-doped silicon, or a combination thereof. The first integrated circuit 30 may be formed in and/or on the substrate 21.

In an embodiment, the first barrier layer 44 may be formed to surround the side surface and bottom of the first conductive layer 45. The first barrier layer 44 may include Ti, TiN, Ta, TaN, WN, or a combination thereof. The first conductive layer 45 may include a single layer or a multilayer. The first conductive layer 45 may include metal, metal nitride, metal oxide, metal silicide, polysilicon, conductive carbon, or a combination thereof. The first conductive layer 45 may include Cu, Al, Ni, Co, Ru, W, WN, Ti, TiN, Ta, TaN, Sn, Pt, Au, Ag, or a combination thereof. The upper surfaces of the first insulating layer 42 and the first interconnection 46 may form substantially the same plane.

The first etch stop layer 53 may be formed to cover the first insulating layer 42 and the first interconnection 46. The first etch stop layer 53 may include a material which has an etch selectivity with respect to the first interlayer insulating layer 55. In an embodiment, the first etch stop layer 53 may include silicon nitride, silicon carbonitride (SiCN), silicon oxynitride, silicon oxycarbonitride (SiOCN), or a combination thereof.

The first interlayer insulating layer 55 may be thicker than the first etch stop layer 53. The first interlayer insulating layer 55 may include a single layer or a multilayer. The first interlayer insulating layer 55 may include at least two selected from the group consisting of Si, O, N, C and B. The first interlayer insulating layer 55 may include silicon oxide, silicon nitride, silicon oxynitride, low-k dielectric, high-k dielectric, or a combination thereof. In an embodiment, the first interlayer insulating layer 55 may include a silicon oxide layer.

The first capping layer 57 may include a material different from the first interlayer insulating layer 55. In an embodiment, the first capping layer 57 may include silicon carbonitride (SiCN), silicon nitride, or a combination thereof. The mask pattern 59 may include a photoresist pattern, a hardmask pattern, or a combination thereof.

Forming the first pad trench 62T and the first dummy trench 63T may include an anisotropic etching process using the mask pattern 59 as an etch mask. For the sake of simplicity, the first pad trench 62T and the first dummy trench 63T are illustrated as having the same depth. However, it is to be noted that the first pad trench 62T and the first dummy trench 63T may be formed to have different depths. The sidewalls of the first pad trench 62T and the first dummy trench 63T may be formed to have various slopes, but descriptions will be made on that each of the first pad trench 62T and the first dummy trench 63T has an inverted trapezoid shape.

The first pad trench 62T and the first dummy trench 63T may pass through the first capping layer 57 and extend into the first interlayer insulating layer 55. The horizontal width of the first dummy trench 63T may be smaller than the horizontal width of the first pad trench 62T. The horizontal widths of the first pad trench 62T and the first dummy trench 63T may mean horizontal widths at the same vertical level from a horizontal line which passes through the upper surface of the substrate 21. The first capping layer 57 and the first interlayer insulating layer 55 may be exposed on the sidewalls of the first pad trench 62T and the first dummy trench 63T. The first interlayer insulating layer 55 may be exposed at the bottoms of the first pad trench 62T and the first dummy trench 63T.

Referring to FIG. 6, the mask pattern 59 may be removed, and a spacer layer 65L which covers the first capping layer 57 and covers the inner walls of the first pad trench 62T and the first dummy trench 63T may be formed. The spacer layer 65L may conformally cover the sidewall and bottom of the first pad trench 62T. Due to the relatively small horizontal width of the first dummy trench 63T, the spacer layer 65L may be formed to be relatively thick from the bottom toward the top of the first dummy trench 63T.

In an embodiment, the vertical thickness of the spacer layer 65L at the bottom adjacent to the center of the first dummy trench 63T may be greater than the vertical thickness of the spacer layer 65L at the bottom adjacent to the center of the first pad trench 62T. The vertical thickness of the spacer layer 65L at the bottom of the first dummy trench 63T may be greater than the vertical thickness of the spacer layer 65L at the uppermost end of the first capping layer 57. The vertical thickness of the spacer layer 65L at the uppermost end of the first capping layer 57 may be greater than half the minimum horizontal width of the first dummy trench 63T. The vertical thickness of the spacer layer 65L at the uppermost end of the first capping layer 57 may be smaller than half the minimum horizontal width of the first pad trench 62T.

The spacer layer 65L may include silicon oxide, silicon nitride, silicon oxynitride, silicon carbonitride (SiCN), polysilicon, metal, metal oxide, metal nitride, metal silicate, or a combination thereof. In an embodiment, the spacer layer 65L may include a silicon oxide layer.

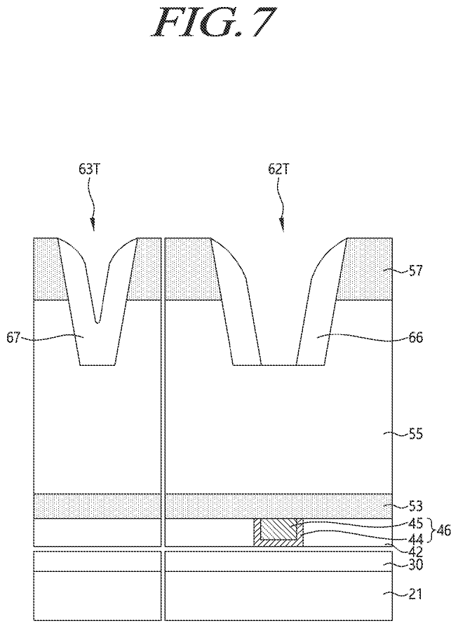

Referring to FIG. 7, by anisotropically etching the spacer layer 65L, the first spacer 66 may be formed in the first pad trench 62T, and the first dummy spacer 67 may be formed in the first dummy trench 63T.

The first spacer 66 may be formed on the sidewall of the first pad trench 62T. The first spacer 66 may be self-aligned on the sidewall of the first pad trench 62T. In an embodiment, the first spacer 66 may cover the sidewall of the first pad trench 62T, and may partially cover the bottom of the first pad trench 62T. At the bottom of the first pad trench 62T, a portion of the first interlayer insulating layer 55 adjacent to the sidewall of the first pad trench 62T may be covered by the first spacer 66, and the remaining portion of the first interlayer insulating layer 55 adjacent to the center of the first pad trench 62T may be exposed.

The first dummy spacer 67 may be formed on the sidewall and bottom of the first dummy trench 63T. The first dummy spacer 67 may completely cover the bottom of the first dummy trench 63T.

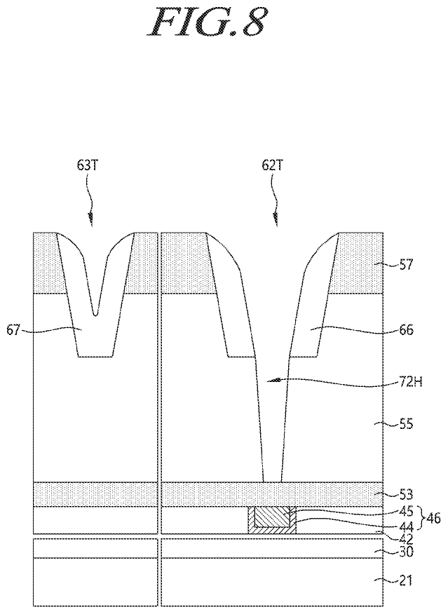

Referring to FIG. 8, by using an anisotropic etching process using the first capping layer 57, the first spacer 66 and the first dummy spacer 67 as an etch mask, the first contact hole 72H which penetrates the first interlayer insulating layer 55 may be formed. The first contact hole 72H may penetrate the bottom of the first pad trench 62T. The first etch stop layer 53 may be exposed at the bottom of the first contact hole 72H. The first contact hole 72H may be self-aligned inside the first spacer 66. The first contact hole 72H may be self-aligned with the center of the first pad trench 62T.

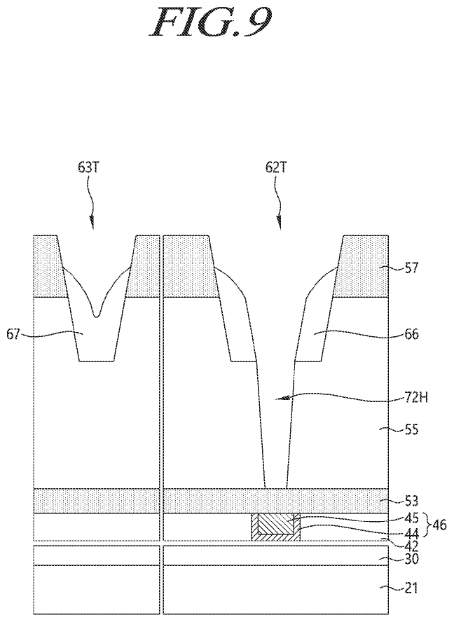

Referring to FIG. 9, by etching the first interlayer insulating layer 55, the first contact hole 72H may be laterally expanded. Expanding the first contact hole 72H may include an isotropic etching process such as a wet etching process. While the first contact hole 72H is expanded, the surfaces of the first spacer 66 and the first dummy spacer 67 may be etched and reduced. In an embodiment, the uppermost ends of the first spacer 66 and the first dummy spacer 67 may be formed at a level lower than the upper surface of the first capping layer 57.

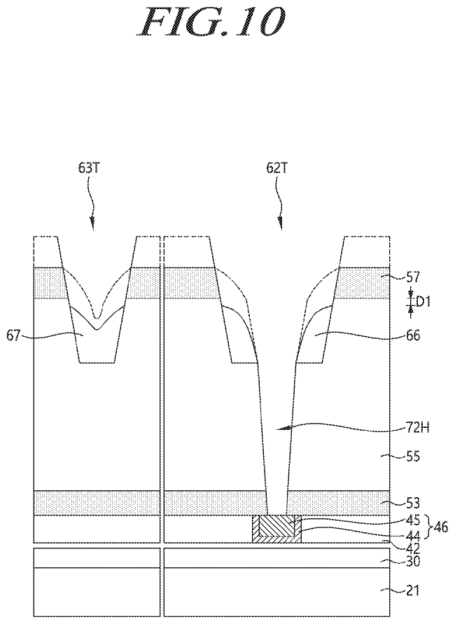

Referring to FIG. 10, by etching the first etch stop layer 53, the first contact hole 72H may be extended downward. The first interconnection 46 may be exposed at the bottom of the first contact hole 72H. In an embodiment, the first etch stop layer 53 may be etched using an anisotropic etching process. While etching the first etch stop layer 53, the first capping layer 57, the first spacer 66 and the first dummy spacer 67 may be etched and reduced.

The first spacer 66 and the first dummy spacer 67 may remain at a level lower than the lower surface of the first capping layer 57. The first capping layer 57 and the first interlayer insulating layer 55 may be exposed on the sidewalls of the first pad trench 62T and the first dummy trench 63T. On the sidewall of the first pad trench 62T, the first interlayer insulating layer 55 may be exposed between the lower surface of the first capping layer 57 and the uppermost end of the first spacer 66. On the sidewall of the first dummy trench 63T, the first interlayer insulating layer 55 may be exposed between the lower surface of the first capping layer 57 and the uppermost end of the first dummy spacer 67.

On the sidewall of the first pad trench 62T, the vertical distance between the lower surface of the first capping layer 57 and the uppermost end of the first spacer 66 may be a first distance D1. The first distance D1 may be 1 nm to 50 nm. In an embodiment, the first distance D1 may be about 10 nm or more. On the sidewall of the first dummy trench 63T, the vertical distance between the lower surface of the first capping layer 57 and the uppermost end of the first dummy spacer 67 may be substantially the same as the first distance D1.

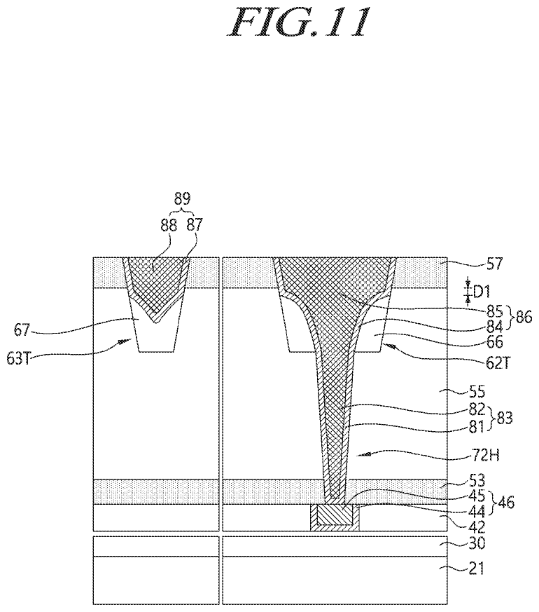

Referring to FIG. 11, the first contact plug 83 may be formed in the first contact hole 72H, the first conductive bonding pattern 86 may be formed in the first pad trench 62T, and the first dummy pattern 89 may be formed in the first dummy trench 63T.

The first contact plug 83 may include a second barrier layer 81 and a second conductive layer 82. The first conductive bonding pattern 86 may include a third barrier layer 84 and a third conductive layer 85. The first dummy pattern 89 may include a fourth barrier layer 87 and a fourth conductive layer 88. The second barrier layer 81 may surround the side surface and bottom of the second conductive layer 82. The second barrier layer 81 may directly contact the first interconnection 46. The third conductive layer 85 may be continuous on the second conductive layer 82. The second conductive layer 82 and the third conductive layer 85 may be integrated with each other. The third barrier layer 84 may surround the side surface of the third conductive layer 85. The third barrier layer 84 may be continuous on the second barrier layer 81. The second barrier layer 81 and the third barrier layer 84 may be integrated with each other. The fourth barrier layer 87 may surround the side surface and bottom of the fourth conductive layer 88.

The second barrier layer 81, the third barrier layer 84 and the fourth barrier layer 87 may include the same material layer formed at substantially the same time. The second barrier layer 81, the third barrier layer 84 and the fourth barrier layer 87 may include Ti, TiN, Ta, TaN, WN, or a combination thereof. The second conductive layer 82, the third conductive layer 85 and the fourth conductive layer 88 may include the same material layer formed at substantially the same time. The second conductive layer 82, the third conductive layer 85 and the fourth conductive layer 88 may include metal, metal nitride, metal oxide, or a combination thereof. The second conductive layer 82, the third conductive layer 85 and the fourth conductive layer 88 may include Cu, Al, Ni, Co, Ru, W, WN, Ti, TiN, Ta, TaN, Sn, Pt, Au, Ag, or a combination thereof.

In an embodiment, the second conductive layer 82, the third conductive layer 85 and the fourth conductive layer 88 may include a Cu layer which is formed using an electroplating method. The second conductive layer 82, the third conductive layer 85 and the fourth conductive layer 88 may additionally include seed layers which are formed on the second barrier layer 81, the third barrier layer 84 and the fourth barrier layer 87. However, illustration of the seed layers will be omitted for the sake of simplicity.

Forming the first contact plug 83, the first conductive bonding pattern 86 and the first dummy pattern 89 may include a thin film forming process and a planarization process. The planarization process may include a chemical mechanical polishing (CMP) process, an etch-back process, or a combination thereof. The upper surfaces of the first capping layer 57, the third barrier layer 84, the third conductive layer 85, the fourth barrier layer 87 and the fourth conductive layer 88 may be exposed on substantially the same plane.

The side surface of the first conductive bonding pattern 86 may contact the first capping layer 57, the first interlayer insulating layer 55 and the first spacer 66. The vertical distance of the contact surfaces of the first conductive bonding pattern 86 and the first interlayer insulating layer 55 may be the first distance D1.

The horizontal width of the first contact plug 83 may be smaller than the horizontal width of the first conductive bonding pattern 86. The first contact plug 83 may be self-aligned inside the first spacer 66. The first contact plug 83 may be self-aligned with the center of the first pad trench 62T. The first contact plug 83 may be self-aligned with the center of the first conductive bonding pattern 86.

The first dummy pattern 89 may contact the first capping layer 57, the first interlayer insulating layer 55 and the first dummy spacer 67. The vertical distance of the contact surfaces of the first dummy pattern 89 and the first interlayer insulating layer 55 may be the first distance D1. The first dummy spacer 67 may remain between the first dummy pattern 89 and the bottom of the first dummy trench 63T.

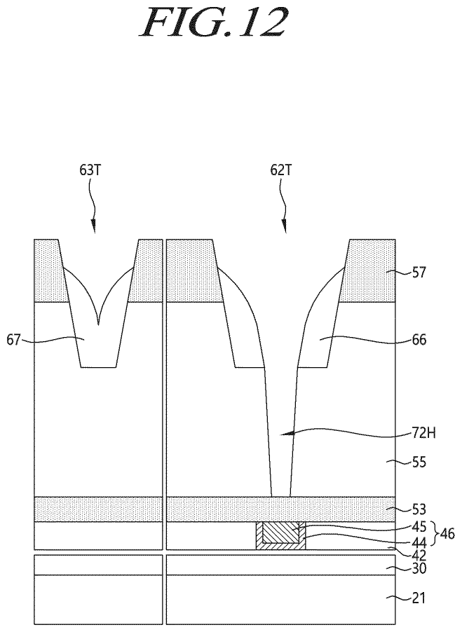

FIG. 12 is a cross-sectional view for describing a method for forming a semiconductor device in accordance with an embodiment of the present disclosure.

Referring to FIG. 12, the first etch stop layer 53 may be exposed at the bottom of the first contact hole 72H. The uppermost ends of the first spacer 66 and the first dummy spacer 67 may be formed at a level lower than the uppermost end of the first capping layer 57. The first contact plug 83, the first conductive bonding pattern 86 and the first dummy pattern 89 may be formed in a method similar to that described above with reference to FIGS. 10 and 11. The process of expanding the first contact hole 72H described above with reference to FIG. 9 may be omitted.

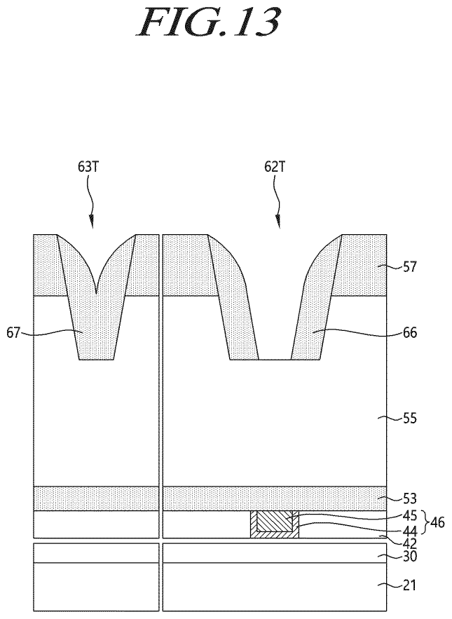

FIGS. 13 to 16 are cross-sectional views for describing a method for forming a semiconductor device in accordance with an embodiment of the present disclosure.

Referring to FIG. 13, the first spacer 66 and the first dummy spacer 67 may include a material similar to the first capping layer 57. In an embodiment, the first capping layer 57 may include silicon carbonitride (SiCN), and the first spacer 66 and the first dummy spacer 67 may include silicon carbonitride (SiCN), silicon nitride, silicon oxynitride, or a combination thereof.

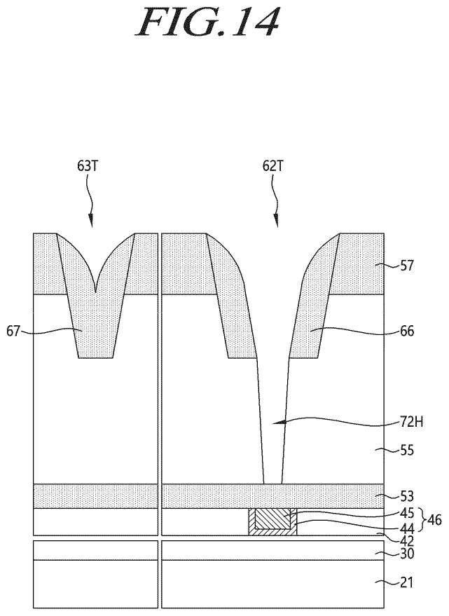

Referring to FIG. 14, the first etch stop layer 53 may be exposed at the bottom of the first contact hole 72H. To this end, an anisotropic etching process may be used. The first spacer 66 and the first dummy spacer 67 may contact the first capping layer 57 and the first interlayer insulating layer 55. The uppermost ends of the first spacer 66 and the first dummy spacer 67 may be formed at a level similar to the uppermost end of the first capping layer 57.

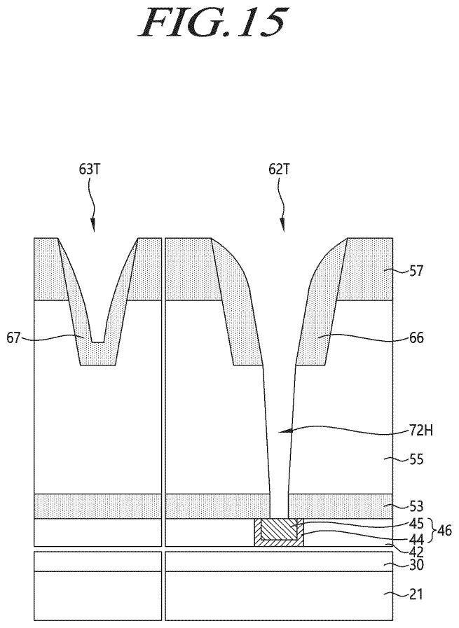

Referring to FIG. 15, by etching the first etch stop layer 53, the first contact hole 72H may be extended downward. The uppermost ends of the first spacer 66 and the first dummy spacer 67 may be formed at a level similar to the uppermost end of the first capping layer 57.

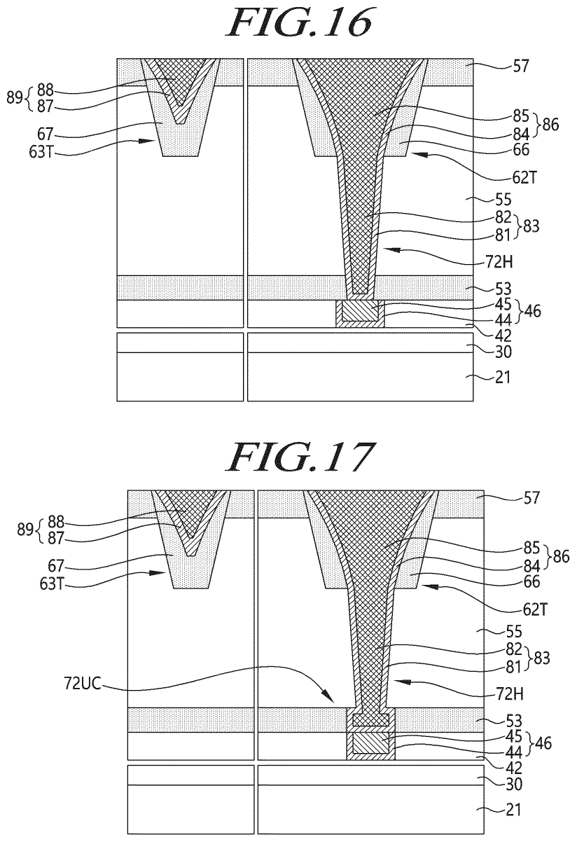

Referring to FIG. 16, the first contact plug 83 may be formed in the first contact hole 72H, the first conductive bonding pattern 86 may be formed in the first pad trench 62T, and the first dummy pattern 89 may be formed in the first dummy trench 63T. The uppermost ends of the first spacer 66 and the first dummy spacer 67 may remain at a level similar to the uppermost end of the first capping layer 57. In an embodiment, the upper surfaces of the first capping layer 57, the first spacer 66, the first dummy spacer 67, the third barrier layer 84, the third conductive layer 85, the fourth barrier layer 87 and the fourth conductive layer 88 may be exposed on substantially the same plane.

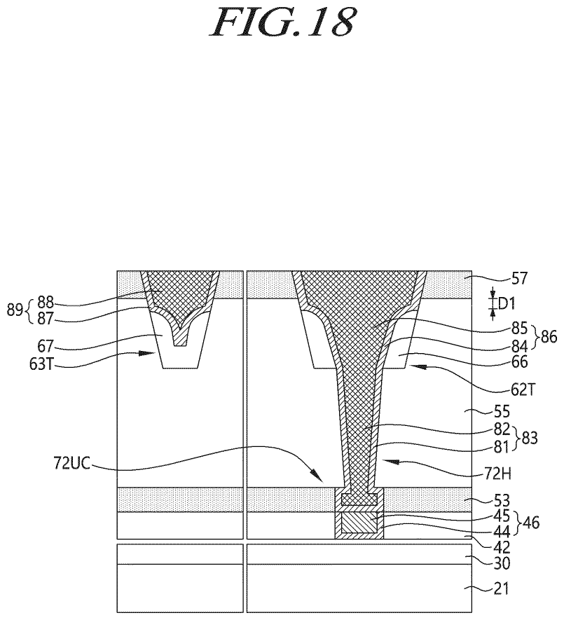

FIGS. 17 and 18 are cross-sectional views for describing a method for forming a semiconductor device in accordance with an embodiment of the present disclosure.

Referring to FIG. 17, in an embodiment, when etching the first etch stop layer 53 to extend the first contact hole 72H downward, an isotropic etching process may be used. An undercut region 72UC may be formed under the first interlayer insulating layer 55. The first contact plug 83 may fill the interior of the undercut region 72UC. The contact surfaces of the first contact plug 83 and the first interconnection 46 may be expanded. The first spacer 66 and the first dummy spacer 67 may contact the first capping layer 57.

Referring to FIG. 18, in an embodiment, after forming a structure shown in FIG. 10, the first etch stop layer 53 is etched (e.g., through an isotropic etching process) to extend the first contact hole 72H downward. The first contact plug 83 may fill the interior of the undercut region 72UC. On the sidewall of the first pad trench 62T, the vertical distance between the lower surface of the first capping layer 57 and the uppermost end of the first spacer 66 may be a first distance D1. On the sidewall of the first dummy trench 63T, the vertical distance between the lower surface of the first capping layer 57 and the uppermost end of the first dummy spacer 67 may be substantially the same as the first distance D1.

Although various embodiments of the disclosure have been described for illustrative purposes, those skilled in the art will appreciate that various modifications, additions and substitutions are possible, without departing from the scope and spirit of the present disclosure. Therefore, the embodiments disclosed above and in the accompanying drawings should be considered in a descriptive sense only and not for limiting the technological scope. The technological scope of the present disclosure is not limited by the embodiments and the accompanying drawings. The spirit and scope of the present disclosure should be interpreted in connection with the appended claims and encompass all equivalents falling within the scope of the appended claims. Furthermore, the embodiments may be combined to form additional embodiments.

What is claimed is:

1. A semiconductor device comprising:
an interconnection disposed on a substrate;
an interlayer insulating layer disposed on the interconnection;
a capping layer disposed on the interlayer insulating layer;
a conductive bonding pattern disposed in a pad trench which passes through the capping layer and extends into the interlayer insulating layer;
a spacer disposed in the pad trench, and contacting a side surface of the conductive bonding pattern; and
a contact plug disposed in a contact hole which passes through the interlayer insulating layer and is aligned with a center of the pad trench,
wherein the contact plug contacts the interconnection, and
wherein the conductive bonding pattern is continuous to the contact plug.

2. The semiconductor device according to claim 1, wherein
upper surfaces of the capping layer and the conductive bonding pattern form substantially a same plane, and
an uppermost end of the spacer is disposed at a level equal to or lower than a level of an uppermost end of the conductive bonding pattern.

3. The semiconductor device according to claim 1, wherein the spacer comprises silicon oxide, silicon nitride, silicon oxynitride, silicon carbonitride (SiCN), polysilicon, metal, metal oxide, metal nitride, metal silicate, or a combination thereof.

4. The semiconductor device according to claim 1, wherein:
the spacer comprises silicon oxide; and
an uppermost end of the spacer is disposed at a lower level than an uppermost end of the interlayer insulating layer.

5. The semiconductor device according to claim 4, wherein
a vertical distance between a lower surface of the capping layer and an uppermost end of the spacer is about 10 nm to 50 nm.

6. The semiconductor device according to claim 1, wherein
the spacer comprises silicon nitride, silicon carbonitride (SiCN), silicon oxynitride, or a combination thereof, and
upper surfaces of the capping layer, the spacer and the conductive bonding pattern form substantially a same plane.

7. The semiconductor device according to claim 1, wherein the spacer surrounds a side surface of the conductive bonding pattern.

8. The semiconductor device according to claim 1, wherein the contact plug is aligned according to a profile of the spacer.

9. The semiconductor device according to claim 1, wherein:
the capping layer comprises silicon carbonitride (SiCN), silicon nitride, or a combination thereof; and
the interlayer insulating layer comprises silicon oxide.

10. The semiconductor device according to claim 1, further comprising an etch stop layer disposed between the interconnection and the interlayer insulating layer,
wherein the contact plug contacts the interconnection by passing through the etch stop layer.

11. The semiconductor device according to claim 1, further comprising:
a dummy pattern disposed in a dummy trench which passes through the capping layer and extends into the interlayer insulating layer; and
a dummy spacer disposed in the dummy trench, and contacting a side surface and bottom of the dummy pattern.

12. The semiconductor device according to claim 11, wherein
the dummy trench has a narrower width than the pad trench.

13. The semiconductor device according to claim 11, wherein:
upper surfaces of the capping layer, the dummy pattern and the conductive bonding pattern form substantially a same plane; and
an uppermost end of the dummy spacer is disposed at a level equal to or lower than a level of an uppermost end of the dummy pattern.

14. The semiconductor device according to claim 11, wherein
the dummy spacer comprises a same material as the spacer.

15. The semiconductor device according to claim 11, wherein:
the dummy spacer comprises silicon oxide; and
an uppermost end of the dummy spacer is disposed at a lower level than an uppermost end of the interlayer insulating layer.

16. A semiconductor device comprising:
a first structure; and
a second structure bonded onto the first structure,
wherein the first structure comprises
a first integrated circuit;
a first interconnection disposed on the first integrated circuit;
a first interlayer insulating layer disposed on the first interconnection;
a first capping layer disposed on the first interlayer insulating layer;
a first conductive bonding pattern disposed in a first pad trench which passes through the first capping layer and extends into the first interlayer insulating layer;
a first spacer disposed in the first pad trench, and contacting a side surface of the first conductive bonding pattern; and
a first contact plug disposed in a first contact hole which passes through the first interlayer insulating layer and is aligned with a center of the first pad trench,
wherein the first contact plug contacts the first interconnection, and
wherein the first conductive bonding pattern is continuous to the first contact plug.

17. The semiconductor device according to claim 16, wherein the second structure comprises:
a second integrated circuit;
a second interconnection disposed on the second integrated circuit;
a second interlayer insulating layer disposed on the second interconnection;
a second capping layer disposed on the second interlayer insulating layer;
a second conductive bonding pattern disposed in a second pad trench which passes through the second capping layer and extends into the second interlayer insulating layer;
a second spacer disposed in the second pad trench, and contacting a side surface of the second conductive bonding pattern; and
a second contact plug disposed in a second contact hole which passes through the second interlayer insulating layer and is aligned with a center of the second pad trench,
wherein the second capping layer faces the first capping layer, and
wherein the second conductive bonding pattern is bonded onto the first conductive bonding pattern.

18. A semiconductor device comprising:
a first structure; and
a second structure bonded onto the first structure,
wherein the first structure comprises
a first integrated circuit;
a first interconnection disposed on the first integrated circuit;
a first interlayer insulating layer disposed on the first interconnection;
a first capping layer disposed on the first interlayer insulating layer;
a first conductive bonding pattern disposed in a first pad trench which passes through the first capping layer and extends into the first interlayer insulating layer;
a first dummy pattern disposed in a first dummy trench which passes through the first capping layer and extends into the first interlayer insulating layer;
a first spacer disposed in the first pad trench, and contacting a side surface of the first conductive bonding pattern;
a first dummy spacer disposed in the first dummy trench, and contacting a side surface and bottom of the first dummy pattern; and
a first contact plug disposed in a first contact hole which passes through the first interlayer insulating layer and is aligned with a center of the first pad trench,
wherein the first contact plug contacts the first interconnection, and
wherein the first conductive bonding pattern is continuous to the first contact plug.

19. The semiconductor device according to claim 18, wherein the second structure comprises:
a second integrated circuit;
a second interconnection disposed on the second integrated circuit;
a second interlayer insulating layer disposed on the second interconnection;
a second capping layer disposed on the second interlayer insulating layer;
a second conductive bonding pattern disposed in a second pad trench which passes through the second capping layer and extends into the second interlayer insulating layer;
a second dummy pattern disposed in a second dummy trench which passes through the second capping layer and extends into the second interlayer insulating layer;
a second spacer disposed in the second pad trench, and contacting a side surface of the second conductive bonding pattern;
a second dummy spacer disposed in the second dummy trench, and contacting a side surface and bottom of the second dummy pattern; and
a second contact plug disposed in a second contact hole which passes through the second interlayer insulating layer and is aligned with a center of the second pad trench,
wherein the second capping layer faces the first capping layer,
wherein the second conductive bonding pattern is bonded onto the first conductive bonding pattern, and
wherein the second dummy pattern is bonded onto the first dummy pattern.

20. The semiconductor device according to claim 18, wherein
the first dummy trench has a narrower width than the first pad trench.
